(19) United States
(12) Patent Application Publication
(10) Pub. No.: US 2015/0147513 A1
(43) Pub. Date: May 28, 2015

(54) DEVICE AND FORMING METHOD

(71) Applicant: Kabushiki Kaisha Toshiba, Tokyo (JP)

(72) Inventors: Tomoko Shiroishi, Hamura-shi (JP); Shinichi Kido, Hamura-shi (JP)

(21) Appl. No.: 14/305,558

(22) Filed: Jun. 16, 2014

Related U.S. Application Data
(60) Provisional application No. 61/907,959, filed on Nov. 22, 2013.

(51) Int. Cl. H01Q 1/22; H05K 5/02; B29D 99/00

(52) U.S. Cl. CPC H01Q 1/2266; B29D 99/006; H05K 5/02
USPC 428/58; 343/702; 264/255

(57) ABSTRACT

According to one embodiment, a device includes a first portion and a second portion. The first portion is made of a first material and includes a first wall extending in a first direction, an edge portion of the first wall, and a projection protruding from the edge portion in a second direction intersecting the first direction. The second portion is made of a second material and includes a second wall extending from the edge portion of the first wall, and a fastening portion configured to be fastened to the projection.

### FIELD

Embodiments described herein relate generally to a device and a forming method.

### BACKGROUND

A device may comprise a plurality of portions each made of different materials.

### BRIEF DESCRIPTION OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view illustrating a portable computer according to a first embodiment;

FIG. 2 is an exemplary plan view illustrating a top cover and an antenna cover in the first embodiment;

FIG. 3 is an exemplary plan view illustrating the top cover and the antenna cover with a view from the opposite side of FIG. 2, in the first embodiment;

FIG. 4 is an exemplary plan view illustrating a portion of the top cover and a portion of the antenna cover in the first embodiment;

FIG. 5 is an exemplary perspective view illustrating a portion of the top cover in the first embodiment;

FIG. 6 is an exemplary cross-sectional view illustrating a portion of the top cover and a portion of the antenna cover in the first embodiment;

FIG. 7 is an exemplary cross-sectional view illustrating a portion of the top cover and a portion of the antenna cover illustrated with an enlarged view, in the first embodiment;

FIG. 8 is an exemplary cross-sectional view illustrating a first mold, a second mold, and the top cover in the first embodiment;

FIG. 9 is an exemplary cross-sectional view illustrating a portion of a top cover and a portion of an antenna cover according to a second embodiment; and

FIG. 10 is an exemplary cross-sectional view illustrating a portion of a display portion according to a third embodiment.

### DETAILED DESCRIPTION

Various embodiments according to the present invention will now be described with reference to the accompanying drawings. In general, according to one embodiment, a device generally comprises a first portion and a second portion. The first portion is made of a first material and comprises a first wall extending in a first direction, an edge portion of the first wall and a projection extending in a second direction intersecting the first direction from the edge portion of the first wall. The second portion is made of a second material and comprises a second wall extending from the edge portion of the first wall and a fastening portion configured to be fastened to the projection.

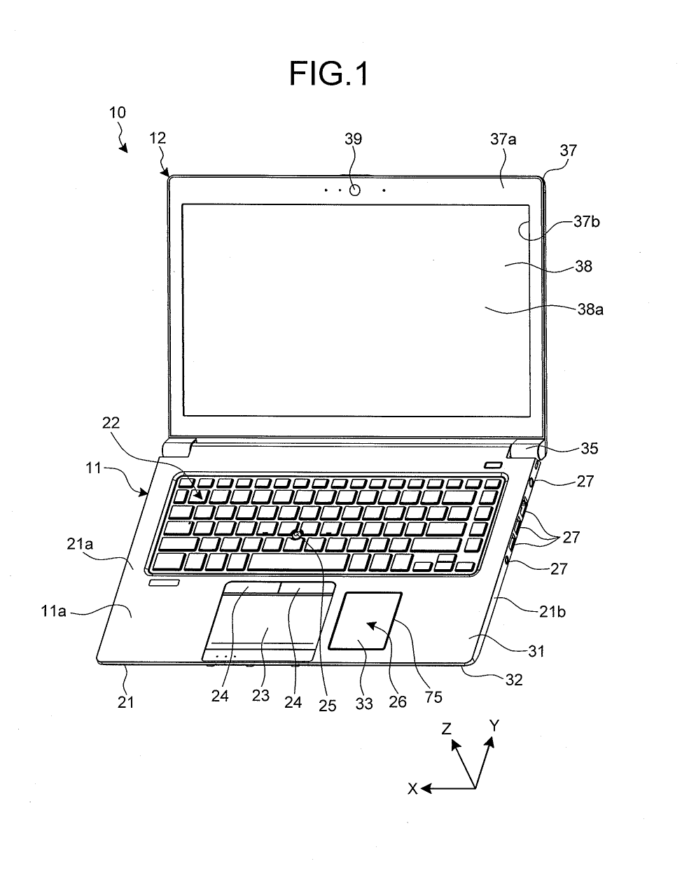

The following describes a first embodiment with reference to FIGS. 1 to 8. In this specification, basically, the user side is defined as a front side, the side far from the user is defined as a rear side, the left side viewed from the user is defined as a left direction, the right side viewed from the user is defined as a right direction, the up side viewed from the user is defined as an upward direction, and the down side viewed from the user is defined as a downward direction. Hereinafter, plural expressions may be provided for the configuration elements in embodiments or the descriptions on the configuration elements. Other expressions not provided herein will not be prevented from being used. In addition, other expressions will not be prevented from being used for the configuration elements and descriptions in which no plural expressions are provided.

FIG. 1 is a perspective view illustrating a portable computer 10 according to a first embodiment. The portable computer 10 is an example of a device and may also be referred to as an electronic device or a machine.

The device is not limited to the portable computer 10, and may be a television set, a display, a mobile phone, a smart phone, a tablet, a game console, a printer, a box, or other devices. The device may not comprise any electronic component.

As illustrated in FIG. 1, the portable computer 10 comprises a base portion 11 and a display portion 12. The base portion 11 and the display portion 12 may also be referred to as a part, a component, a unit, or a module.

As illustrated in the drawings, an X-axis, a Y-axis, and a Z-axis are defined in this specification. The X-axis, the Y-axis, and the Z-axis are orthogonal to each other. The X-axis is along the width (the lateral length) of the base portion 11. The Y-axis is along the depth (the back-and-forth length) of the base portion 11. The Z-axis is along the thickness of the base portion 11 (the vertical length).

The base portion 11 comprises a first housing 21, a keyboard 22, a touchpad 23, a pair of buttons 24, a pointing stick 25, a near field communication (NFC) portion 26, and a plurality of connectors 27. The first housing 21 is an example of a housing and may also be referred to as a wall, an outer shell, an exterior part, or a case, for example. The keyboard 22, the touchpad 23, the buttons 24, and the pointing stick 25 may also be referred to as an input device, for example. The NFC portion 26 is an example of a component and may also be referred to as a communication portion.

The first housing 21 is in a flat box shape. The first housing 21 comprises a top cover 31, a bottom cover 32, and an antenna cover 33. The top cover 31 is an example of the first portion and may also be referred to as a metal portion, a member, a base member, a frame, or a wall, for example. The antenna cover 33 is an example of the second portion, and may also be referred to as a resin portion, a member, a cover, or a wall, for example.

The top cover 31 is attached to the bottom cover 32. The top cover 31 forms an upper face 21a of the first housing 21 and a side face 21b perpendicular to the upper face 21a of the first housing 21. The upper face 21a is a face that faces the direction along the Z-axis. The side face 21b is a face that faces the direction along the X-axis. The bottom cover 32 forms the bottom face of the first housing 21 located on the opposite side of the upper face 21a.

The keyboard 22, the touchpad 23, the buttons 24, and the pointing stick 25 are provided on the upper face 21a of the first housing 21. The touchpad 23, the buttons 24, and the NFC portion 26 are located on a palm rest 11a of the base portion 11. The touchpad 23 and the button 24 are provided side by side with the NFC portion 26 along the X-axis.

The keyboard 22, the touchpad 23, the buttons 24, and the pointing stick 25 are operated by a user, for example. The NFC portion 26 performs wireless communications with an IC card, for example.

The connectors 27 open to the side face 21b of the first housing 21. The connectors 27 are a universal serial bus (USB) connector, a local area network (LAN) connector, an audio input/output port, and a power source connector, for example.

The display portion 12 is installed at the rear end portion of the base portion 11 by using a hinge 35. The display portion 12 comprises a second housing 37, a display module 38, and a camera 39.

The second housing 37 is in a flat box shape. The second housing 37 houses the display module 38 and the camera 39. The second housing 37 comprises a front face 37a and a display opening 37b provided on the front face 37a. The display opening 37b is covered with a transparent glass, for example.

The display module 38 comprises a screen 38a. The screen 38a is exposed by the display opening 37b of the second housing 37. The display module 38 displays an image or images on the screen 38a. Examples of images include a moving image, a still image, and a monochrome screen.

The camera 39 opens to the front face 37a of the second housing 37. The camera 39 captures a picture and detects the lightness of the outside. The brightness of the screen 38a of the display module 38 is changed depending on the lightness of the outside detected by the camera 39.

The display portion 12 can move rotationally between a closed position and an opening position. If the display portion 12 is in the closed position, the front face 37a of the second housing 37 faces the upper face 21a of the first housing 21. If the display portion 12 is in the opening position, the display portion 12 stands at an angle, for example, on the base portion 11.

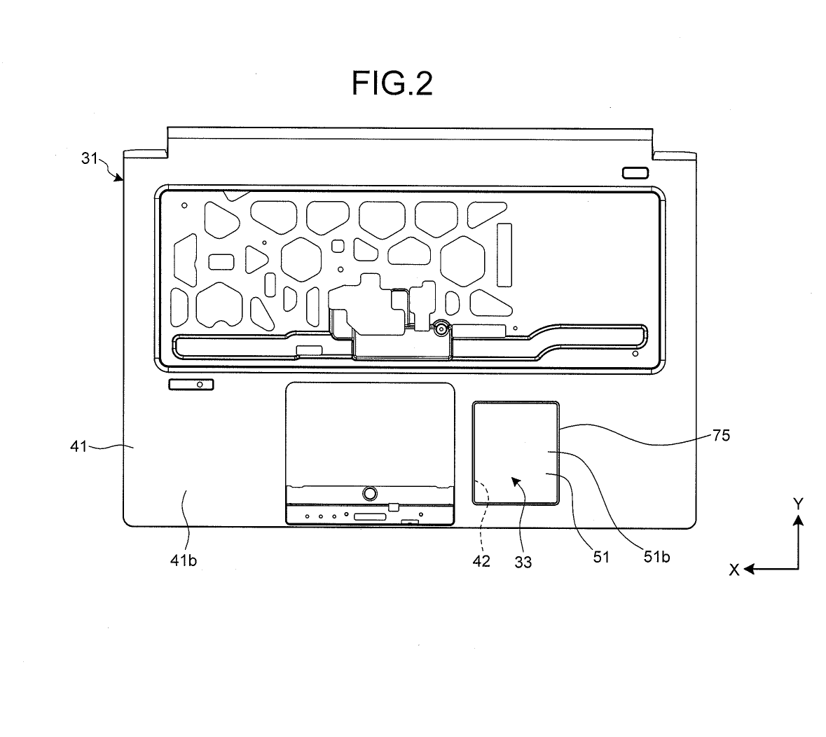

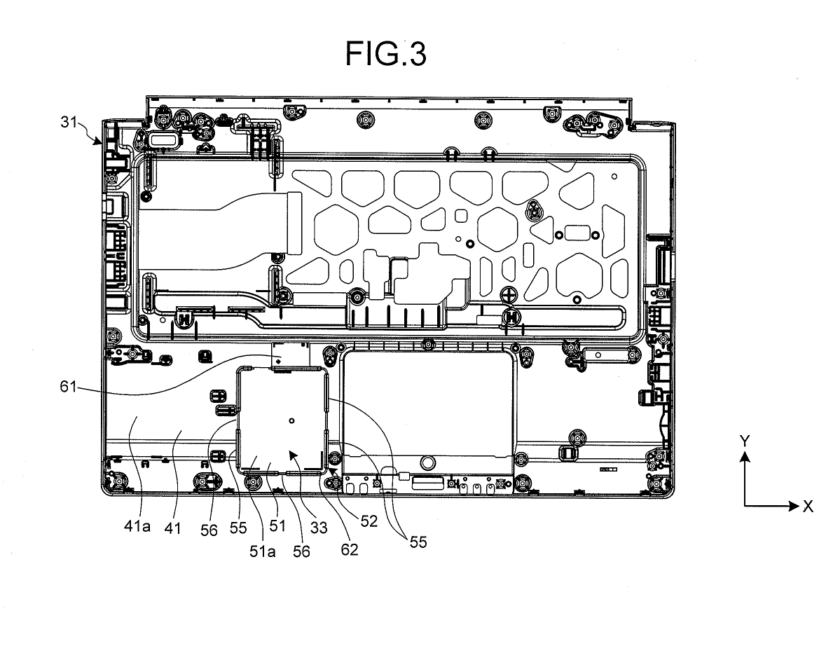

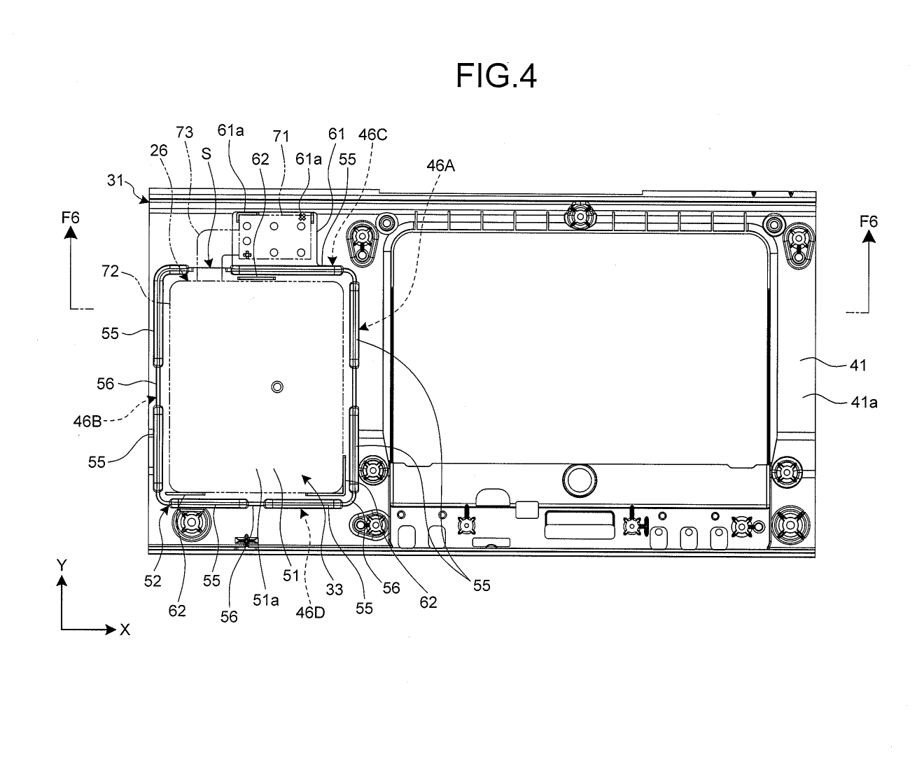

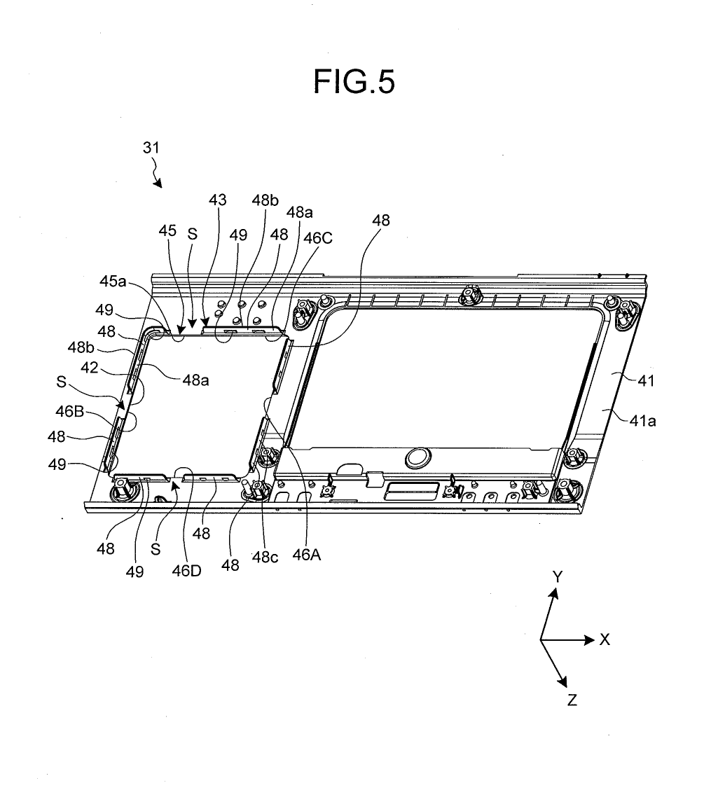

FIG. 2 is a plan view illustrating the top cover 31 and the antenna cover 33 according to the first embodiment. FIG. 3 is a plan view illustrating the top cover 31 and the antenna cover 33 with a view from the opposite side of FIG. 2, in the first embodiment. FIG. 4 is an enlarged plan view illustrating a portion of the top cover 31 and a portion of the antenna cover 33 in the first embodiment. FIG. 5 is a perspective view illustrating a portion of the top cover 31.

The top cover 31 is made of a magnesium alloy. The magnesium alloy is an example of a first material. The top cover 31 may be made of other materials such as other metallic materials, synthetic resins or ceramics.

The antenna cover 33 is made of a synthetic resin including a glass fiber, for example. The synthetic resin including a glass fiber is an example of the second material, which is an insulator and a non-magnetic body. The antenna cover 33 may also be made of other materials such as other synthetic resins, metals or ceramics.

The synthetic resin including a glass fiber has, for example, a larger coefficient of contraction (coefficient of dimensional change) than the magnesium alloy forming the top cover 31. The coefficient of contraction refers to a coefficient of thermal expansion, for example. The synthetic resin including a glass fiber has a coefficient of contraction of which value is closer to the magnesium alloy than a synthetic resin comprising no glass fiber. The second material has a coefficient of contraction of which value is equal to or larger than that of the first material.

The material that forms the top cover 31 differs from the material that forms the antenna cover 33. However, the material that forms the top cover 31 may be the same as the material that forms the antenna cover 33. For example, the top cover 31 and the antenna cover 33 may be made of synthetic resins of the same kind of material having different colors from each other.

The top cover 31 and the antenna cover 33 are formed integrally through so-called “outsert-molding”. The top cover 31 and the antenna cover 33 may be formed through other methods such as so-called “insert molding”, “double molding”, or “injection molding”.

As illustrated in FIG. 5, the top cover 31 comprises a first wall 41, an opening 42, and a projection 43. The first wall 41 may also be referred to as, for example, a portion, a member, or an extending portion. The opening 42 may also be referred to as, for example, a hole, a recess, an exposing portion, or an inserted portion. The projection 43 may also be referred to as, for example, a projecting portion, a protrusion, a wall, or a rib.

The first wall 41 is a substantially flat portion that extends along the X-axis and the Y-axis. The direction along the X-axis and the direction along the Y-axis are examples of the first direction. The first wall 41 forms a portion of the palm rest 11a of the base portion 11. The first wall 41 may also form another portion of the base portion 11.

As illustrated in FIGS. 2 and 5, the first wall 41 comprises an inner face 41a and an outer face 41b. The inner face 41a is an example of a first face. The outer face 41b is an example of a second face. The inner face 41a faces the inside of the first housing 21 in the direction along the Z-axis. The outer face 41b is located on the opposite side of the inner face 41a and is exposed to the outside.

The opening 42 is provided on the first wall 41. The opening 42 is located on the position where the NFC portion 26 is disposed. The opening 42 is a hole in a substantially rectangular shape (quadrangle) and opens to the inner face 41a and the outer face 41b of the first wall 41. The opening 42 may also be in a circular shape, for example, or a recess and a notch, alternatively.

The first wall 41 comprises an edge portion 45. The edge portion 45 is a frame-like portion in a rectangular shape (quadrangle) defining the opening 42. That is, the edge portion 45 comprises two side portions 46A and 46B extending along the Y-axis; and two side portions 46C and 46D extending along the X-axis. The side portion 46A faces the side portion 46B and is located on a position closer to the touchpad 23 than the side portion 46B. The side portion 46C faces the side portion 46D and is located on a position closer to the keyboard 22 than the side portion 46D. If the opening 42 is a recess or a notch, the edge portion 45 comprises three side portions, for example.

The edge portion 45 comprises an end face 45a that forms the inner circumferential face of the opening 42 and a portion of the first wall 41 located around the opening 42. The end face 45a is an example of an end of the edge. That is, the edge portion 45 comprises a portion of the inner face 41a of the first wall 41 and a portion of the outer face 41b of the first wall 41 both located adjacent to the opening 42. The end face 45a is perpendicular to the inner face 41a and the outer face 41b.

As illustrated in FIG. 5, the projection 43 comprises a plurality of ribs 48. The ribs 48 are examples of a plurality of protruding portions and may also be referred to as projections, protrusions, projecting portions, extending portions, reinforcing portions, or walls, for example.

Each of the ribs 48 protrudes from the inner face 41a of the first wall 41 in the direction along the Z-axis. The direction along the Z-axis is an example of a second direction. The rib 48 is located on the edge portion 45 and extends along the edge portion 45. In other words, each rib 48 extends along the corresponding side portion, that is, the side portion 46A, the side portion 46B, the side portion 46C, or the side portion 46D where each rib 48 is located. The ribs 48 are disposed on the four side portions of the opening 42 formed in a rectangular shape (quadrangle) respectively.

The rib 48 is slightly apart from the opening 42. In other words, the rib 48 is separated from the end face 45a of the edge portion 45. The rib 48 may contact, however, the opening 42 and a first side face 48a of the rib 48 may be continuous with the end face 45a of the edge portion 45. The first side face 48a faces the opening 42. For example, the first side face 48a of the ribs 48 extending along the side portion 46A and the first side face 48a of the ribs 48 extending along the side portion 46B face the direction along the X-axis.

The ribs 48 are disposed apart from each other in the direction along the edge portion 45. In other words, a space S is formed between the ribs 48 adjacent to each other. The projection 43 may comprise one rib surrounding the entire edge portion 45, for example.

The rib 48 comprises a plurality of holes 49. Each of the holes 49 is an example of a hollow and may also be referred to as a slit, an opening, a groove, a dent, a supporting portion, a reinforcing portion, or a filled portion, for example. The hollow is not limited to the hole 49 and may be a dent, a recess, or a notch disposed at an end of the rib 48 in the direction where the edge portion 45 extends, for example. The hole 49 exists between the tip 48b of the rib 48 and the edge portion 45 (the inner face 41a of the first wall 41) in the direction along the Z-axis.

The hole 49 penetrates through the rib 48 in its thickness direction and extends along the edge 45. For example, the holes 49 of the ribs 48 extending along the side portion 46A and the hole 49 of the rib 48 extending along the side portion 46B penetrate through the ribs 48 in the direction along the X-axis and extend in the direction along the Y-axis. In other words, the hole 49 opens to the first side face 48a of the rib 48 and to a second side face 48c of the rib 48. The second side face 48c is located on the opposite side of the first side face 48a. The holes 49 reduce the weight of the top cover 31.

The surface of the inner face 41a of the first wall 41 and the surface of the rib 48 are rougher than the outer face 41b of the first wall 41. For example, the inner face 41a of the first wall 41 and the surface of the rib 48 have larger values of surface roughness than the surface roughness of the outer face 41b of the first wall 41. For example, the inner face 41a of the first wall 41 and the surface of the rib 48 are made to be rough through treatment. In addition, the outer face 41b of the first wall 41 is made to be smooth through painting.

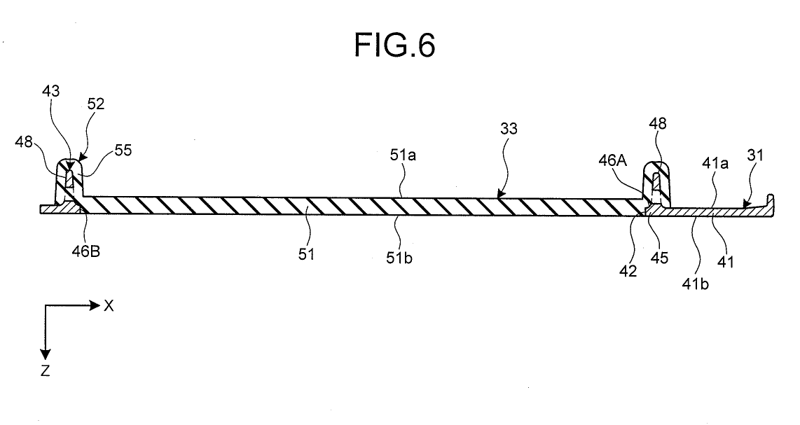

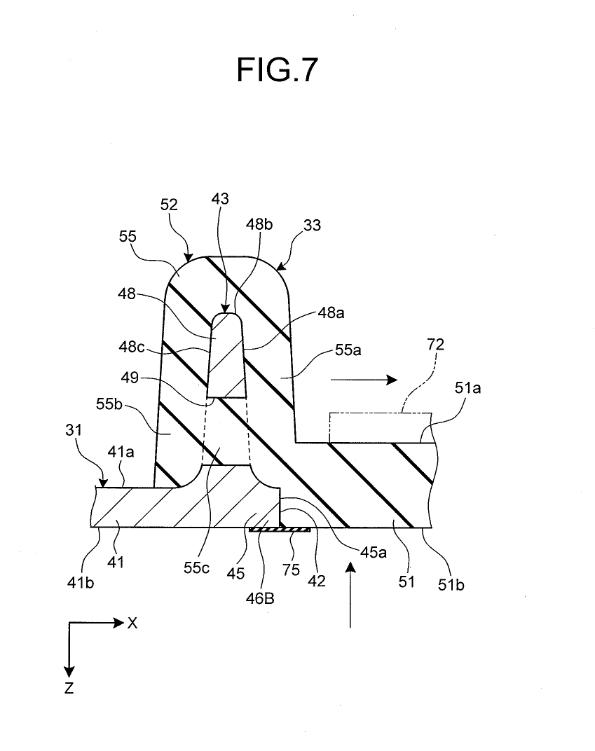

FIG. 6 is a cross-sectional view illustrating a portion of the top cover 31 and a portion of the antenna cover 33 taken along the line F6-F6 in FIG. 4. FIG. 7 is a cross-sectional view illustrating a portion of the top cover 31 and a portion of the antenna cover 33 with an enlarged view.

As illustrated in FIG. 6, the antenna cover 33 comprises a second wall 51 and a covering 52. The second wall 51 may also be referred to as a part, a member, a cover, or an extending portion, for example. The covering 52 is an example of fastening portion, and may also be referred to as an extending portion, a hooked portion, a holded portion, a reinforcing portion, a retainer, or an end portion, for example.

The second wall 51 is a substantially flat portion that extends along the X-axis and the Y-axis. The second wall 51 together with the first wall 41 forms a portion of the palm rest 11a of the base portion 11. The second wall 51 may also form another portion of the base portion 11.

The second wall 51 extends in the direction along the X-axis from the one side portion 46A of the edge portion 45 to the other side portion 46B of the edge portion 45. In other words, the second wall 51 exists between the side portion 46A and the side portion 46B. The second wall 51 also extends in the direction along the Y-axis from the one side portion 46C of the edge portion 45 to the other side portion 46D of the edge portion 45.

As illustrated in FIG. 7, an end portion (the outer circumferential edge) of the second wall 51 in the direction along the X-axis and in the direction along the Y-axis contacts the end face 45a of the edge portion 45. Because the antenna cover 33 is formed integrally with the top cover 31 through the outsert-molding, the end portion of the second wall 51 fastened to the end face 45a of the edge portion 45. Accordingly, the second wall 51 watertightly blocks the opening 42, for example.

The second wall 51 comprises an inner face 51a and an outer face 51b. The outer face 51b is an example of a third surface. The inner face 51a faces the inside of the first housing 21 in the direction along the Z-axis. The outer face 51b is located on the opposite side of the inner face 51a and exposed to the outside. That is, the outer face 51b faces the same direction as the outer face 41b of the first wall 41.

The inner face 51a of the second wall 51 is located on a position closer to the inside of the first housing 21 than the inner face 41a of the first wall 41. In other words, the inner face 51a protrudes from the inner face 41a of the first wall 41. A portion of the second wall 51 covers the edge portion 45 and the inner face 41a of the first wall 41. Accordingly, the inner face 51a partly overlaps with the inner face 41a of the first wall 41.

The outer face 51b of the second wall 51 is continuous with the outer face 41b of the first wall 41. In other words, the outer face 51b forms one surface together with the outer face 41b of the first wall 41. The outer face 51b may protrude or dent from the outer face 41b of the first wall 41. The outer face 51b is painted together with the outer face 41b of the first wall 41.

As illustrated in FIG. 4, the covering 52 is formed integrally with the second wall 51 and comprises a plurality of covering portions 55 and a plurality of connecting portions 56. The covering portion 55 may also be referred to as a part, a fastening part, a fixing part, a reinforcing part, or a filled part, for example. The connecting part 56 may also be referred to as a part, a reinforcing portion, a rib, a wall, or an extending portion.

The covering portion 55 covers and is fastened to the rib 48. As illustrated in FIG. 7, the covering portion 55 comprises an inside portion 55a and an outside portion 55b. The inside portion 55a covers and is fastened to the first side face 48a of the rib 48. The outside portion 55b covers and is fastened to the second side face 48c of the rib 48. Accordingly, the rib 48 is located between the inside portion 55a and the outside portion 55b. The covering portion 55 is fastened to the first and the second side faces 48a and 48c extending in the direction along the Z-axis, thereby ensuring a larger area for fastening in a small space.

The inside portion 55a and the outside portion 55b further cover and is fastened to a portion of the inner face 41a of the first wall 41. The inside portion 55a connects the outside portion 55b to the second wall 51.

A portion of the covering portion 55 located between the inside portion 55a and the outside portion 55b covers and is fastened to the tip 48b of the rib 48. In other words, the covering portion 55 surrounds the tip 48b of the rib 48 to cover the first side face 48a and the second side face 48c.

In other expressions for the covering portion 55, the covering portion 55 is located at an end portion of the second wall 51 and protrudes from the inner face 51a of the second wall 51 in the direction along the Z-axis. The rib 48 is disposed in the covering portion 55. In other words, the covering portion 55 embeds the rib 48. The rib 48 may be partly exposed.

The covering portion 55 further comprises a filled portion 55c. The filled portion 55c is filled in the hole 49 of the rib 48. In other words, the filled portion 55c that is a portion of the covering portion 55 exists in the hole 49. The filled portion 55c extends in the thickness direction of the rib 48 and connects the inside portion 55a of the covering portion 55 to the outside portion 55b of the covering portion 55. For example, in the covering 52 that covers the ribs 48 along the sides 46A and 46B, the filled portion 55c extends in the direction along the X-axis.

As illustrated in FIG. 4, the connecting part 56 protrudes from the inner face 51a of the second wall 51 in the direction along the Z-axis. The connecting part 56 extends from an end portion of the covering portion 55 to an end of the adjacent other covering portion 55 in the direction along the edge portion 45 (the direction along the X-axis or the Y-axis). In other words, the connecting part 56 connects two covering portions 55 adjacent to each other.

The connecting part 56 is thinner than the covering portion 55. In other words, the width of the connecting portions 56 is smaller than that of the covering portion 55. For example, the dimensions along the X-axis of the connecting portions 56 along the sides 46A and 46B are smaller than the dimensions along the X-axis of the covering portion 55 along the sides 46A and 46B. The connecting part 56 thinner than the covering portion 55 suppresses the sink marks generated during formation.

The height of the connecting part 56 protruding from the inner face 51a of the second wall 51 (the dimensions of the connecting part 56 along the Z-axis) is smaller than the height of the covering portion 55 protruding from the inner face 51a of the second wall 51 (the dimensions of the covering portion 55 along the Z-axis). That is, the connecting part 56 is smaller the covering portion 55.

The space S between one rib 48 along the side portion 46C and another adjacent rib 48 is vacant and no connecting part 56 is provided. In other words, the covering 52 does not enclose the opening 42 entirely and partly opens the opening 42.

The antenna cover 33 further comprises an extending portion 61 and a plurality of guide portions 62. The extending portion 61 may also be referred to as a reinforcing portion, a fixed portion, a mounted portion, or a base, for example. The guide portion 62 may also be referred to as a rib, a wall, or an extending portion, for example.

The extending portion 61 is a portion of the antenna cover 33 that is provided between the side portion 46C and the keyboard 22. The extending portion 61 partly covers the inner face 41a of the first wall 41 and is fastened to the inner face 41a.

The extending portion 61 is formed substantially in a rectangular shape (quadrangle). One end of the extending portion 61 leads to the outside portion 55b of the covering portion 55 along the side portion 46C. A plurality of guides 61a protrude from the extending portion 61 in the direction along the Z-axis. The guide 61a is, for example, a pin and a rib.

The guide portion 62 is a rib that protrudes from the inner face 51a of the second wall 51 in the direction along the Z-axis. The guide portion 62 extends toward the adjacent side portion 46A, 46C, or 46D. The height of the guide portion 62 (the dimensions along the Z-axis) is smaller than the height of the connecting part 56, for example.

The NFC portion 26 is housed in the first housing 21. The NFC portion 26 comprises a module 71, an antenna 72, and a cable 73, as illustrated with an alternate long and two short dashes line. The module 71 may also be referred to as a component or a board. The antenna 72 may also be referred to as a communication module.

The module 71 is a printed-circuit board (PCB) on which various electronic parts are mounted, for example. The module 71 is attached to the extending portion 61 with, for example, a double-sided adhesive tape. The module 71 is formed in substantially a rectangular shape (quadrangle) smaller than the extending portion 61. The module 71 is led to a predetermined position by the guide 61a.

The antenna 72 is attached to the inner face 51a of the second wall 51 with, for example, a double-sided adhesive tape. That is, the antenna 72 faces the second wall 51. A spacer made of an insulating material may be interposed between the antenna 72 and the second wall 51, for example.

The cable 73 connects the module 71 to the antenna 72. The cable 73 passes through the space S between one covering portion 55 and another adjacent covering portion 55 that is open without any connecting part 56 provided.

As illustrated in FIG. 2, the base portion 11 further comprises a line 75. The line 75 is an example of marks and may also be referred to as a print, paint, or a coating portion, for example. The line 75 is formed to be a frame in a rectangular shape (quadrangle) through printing, for example. Alternatively, the mark may be achieved with a seal or a tape.

As illustrated in FIG. 7, the line 75 covers a border line between the outer face 41b of the first wall 41 and the outer face 51b of the second wall 51. In other words, the line 75 is provided from the outer face 41b of the first wall 41 to the outer face 51b of the second wall 51. The line 75 extends along the edge portion 45.

In the above-described portable computer 10, a non-contact IC card is approximated to the outer face 51b of the second wall 51, for example. The antenna 72 of the NFC portion 26 generates electrical power through the second wall 51 made of a synthetic resin, by using electromagnetic induction on the coil of the IC card. The IC card communicates with the antenna 72 through the second wall 51 by using the electrical power. That is, the antenna 72 transmits and receives electromagnetic waves through the second wall 51.

As illustrated with an arrow in FIG. 7, for example, the user may press the outer face 51b of the second wall 51 of the antenna cover 33. The covering 52 then is fastened to the rib 48 and the end portion of the second wall 51 also is fastened to the end face 45a of the edge portion 45. In addition, the hole 49 of the rib 48 supports the filled portion 55c of the covering 52. As a result, the antenna cover 33 is suppressed so as not to move in the direction along the Z-axis and not to detach from the top cover 31.

The following describes an example of a method for forming the antenna cover 33 on the top cover 31. The method for forming the antenna cover 33 on the top cover 31 is an example of forming methods. The method for forming the antenna cover 33 on the top cover 31 herein is provided merely for exemplary purpose and is not limiting.

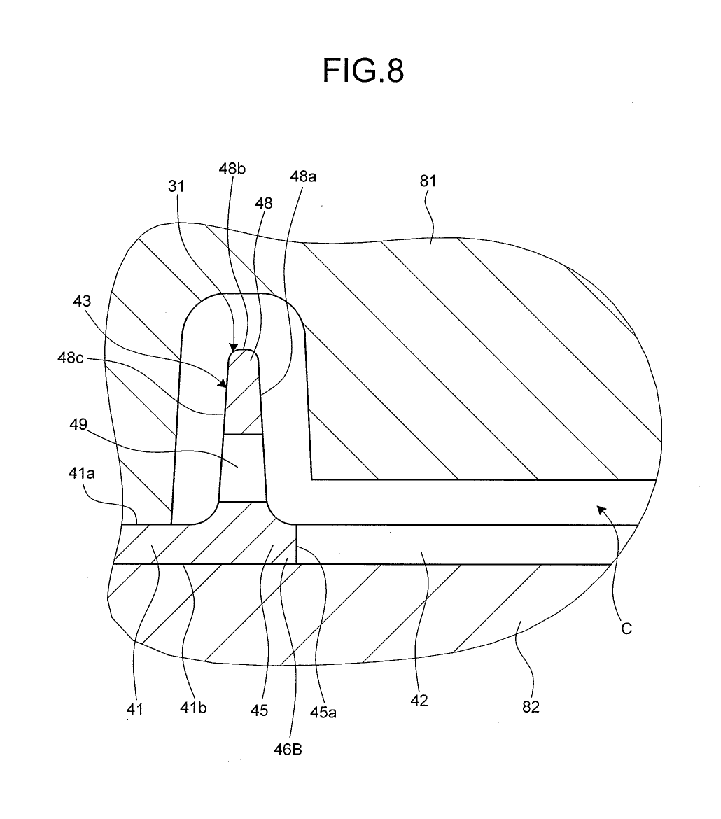

FIG. 8 is a cross-sectional view illustrating a first mold 81, a second mold 82, and the top cover 31. As illustrated in FIG. 8, the first mold 81 and the second mold 82 are mounted on the top cover 31. The first mold 81 contacts the inner face 41a of the first wall 41. The second mold 82 contacts the outer face 41b of the first wall 41.

A cavity C is formed by the first and the second molds 81 and 82 mounted on the top cover 31. Molten material of a synthetic resin (flowable synthetic resin) that has been pressurized is poured into the cavity C. The molten material of the synthetic resin flows into the cavity C and the hole 49 of the rib 48. That is, the molten material of the synthetic resin is filled into the opening 42, around the rib 48 and the hole 49.

By cooling the molten material of the synthetic resin, the antenna cover 33 is formed. The first and the second molds 81 and 82 are removed from the top cover 31, and then the outer face 41b of the first wall 41 and the outer face 51b of the second wall 51 are painted. For drying the paint, the top cover 31 and the antenna cover 33 are put into a furnace.

When cooling the molten material of the synthetic resin and drying the paint, the temperature of the top cover 31 and the temperature of the antenna cover 33 change. The synthetic resin forming the antenna cover 33 has a larger rate of shrinkage than the magnesium alloy forming the top cover 31. Accordingly, as illustrated with an arrow in FIG. 7, the temperature change makes the antenna cover 33 shrink with respect to the top cover 31. In other words, the antenna cover 33 tends to move (shift) in the direction along the X-axis and the direction along the Y-axis with respect to the top cover 31.

The covering 52 of the antenna cover 33 is fastened to the projection 43 of the top cover 31. Specifically, the end portion of the second wall 51 is fastened to the end face 45a of the edge portion 45, the inside portion 55a of the covering portion 55 is fastened to the first side face 48a of the rib 48, the outside portion 55b of the covering portion 55 covers the side face 48c of the rib 48. Accordingly, the projection 43 and the edge portion 45 suppress the shrinkage of the antenna cover 33. For example, the outside portion 55b of the covering portion 55 hooks the second side face 48c of the rib 48, thereby suppressing the shrinkage of the antenna cover 33. This suppresses a crack to be generated between the end face 45a of the edge portion 45 and the end portion of the second wall 51, for example, thereby the appearance of the portable computer 10 can be improved.

The antenna 72 of the NFC portion 26 is attached to the inner face 51a of the second wall 51. On this occasion, the second wall 51 may be pressed in the direction along the Z-axis. A portion of the second wall 51, however, covers the inner face 41a of the first wall 41. Accordingly, the first wall 41 receives the pressed force.

A crack may occur between the end face 45a of the edge portion 45 and the second wall 51, which may be covered by the line 75. The line 75 also indicates the position for the user to pass (hold) the IC card, for example.

In the portable computer 10 according to the first embodiment, the covering 52 is fastened to the projection 43. This suppresses the movement (shift) of the antenna cover 33 with respect to the top cover 31. It is noted that, the movement of the antenna cover 33 with respect to the top cover 31 occurs due to the change in temperature, but this is not limiting. The movement may occur due to aging, for example.

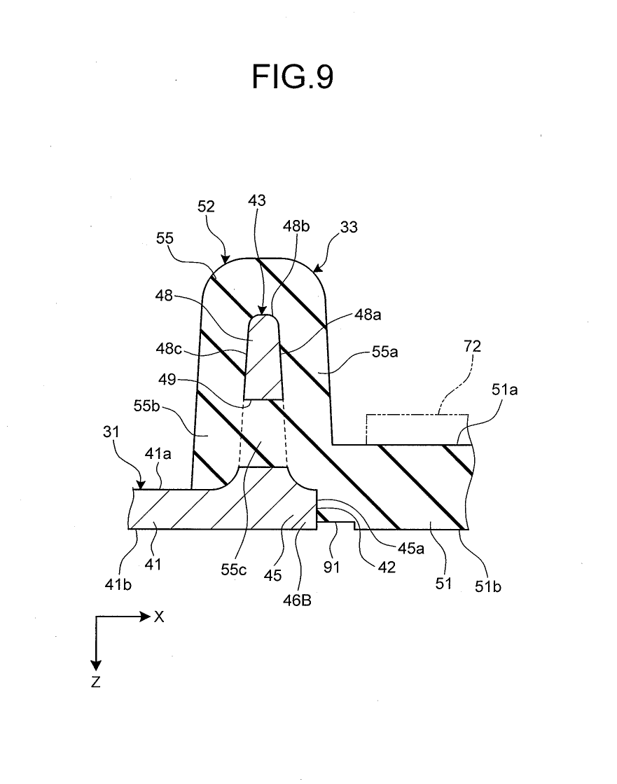

The following describes a second embodiment in this application with reference to FIG. 9. In the descriptions below of a plurality of embodiments, configuration elements having similar functions to the configuration elements that have already been described are designated by reference numerals similar to those of the configuration elements that have already been described, and overlapped explanation thereof may be omitted. The configuration elements having common reference numerals may have different functions and characteristics rather than having exactly the same functions and characteristics.

FIG. 9 is a cross-sectional view illustrating a portion of the top cover 31 and a portion of the antenna cover 33 according to the second embodiment. As illustrated in FIG. 9, a second wall 51 of the second embodiment comprises a recess 91. The recess 91 may also be referred to as a groove.

The recess 91 is provided on the outer face 51b of the second wall 51. The recess 91 is adjacent to an edge portion 45 and extends along the edge portion 45. That is, the recess 91 is a flame-like groove in a rectangular shape (quadrangle) that extends along the end portion of the second wall 51. The recess 91 is defined by a second wall 51 and an end face 45a of the edge portion 45. The recess 91 may be defined by only the second wall 51.

If a crack occurs between the end face 45a of the edge portion 45 and an end portion of the second wall 51, the recess 91 makes the crack hard to be recognized. The recess 91 also indicates the position for the user to pass (hold) the IC card, for example.

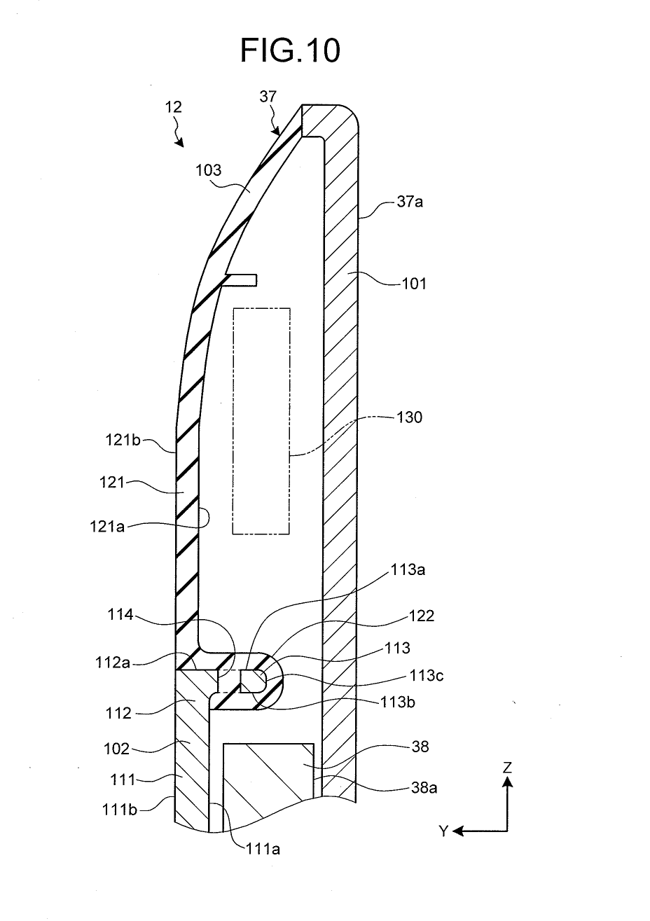

The following describes a third embodiment in this application with reference to FIG. 10. FIG. 10 is a cross-sectional view illustrating a portion of a display portion 12 according to the third embodiment. As illustrated in FIG. 10, a second housing 37 comprises a front cover 101, a rear cover 102, and an antenna cover 103. The rear cover 102 is an example of the first portion. The antenna cover 103 is an example of the second portion. In the description below, the display portion 12 stands so as to be perpendicular to the base portion 11.

The front cover 101 forms a front face 37a of the second housing 37. The rear cover 102 is attached to the front cover 101. The front cover 101 and the rear cover 102 are made of a magnesium alloy, for example. The magnesium alloy is an example of the first material.

The antenna cover 103 is made of a synthetic resin including a glass fiber, for example. The synthetic resin including a glass fiber is an example of the second material. The antenna cover 103 is formed integrally with the rear cover 102 through so-called “outsert-molding”, for example. The rear cover 102 comprises a first wall 111, an edge portion 112, and a projection 113.

The first wall 111 extends in the direction along the Z-axis. The first wall 111 comprises an inner face 111a and an outer face 111b. The inner face 111a faces the inside of the second housing 37 in the direction along the Y-axis. The outer face 111b is located on the opposite side of the inner face 111a.

The edge portion 112 is an end portion of the first wall 111 in the direction along the Z-axis. The edge portion 112 comprises an end face 112a and a portion of the first wall 111 adjacent to the end face 112a. That is, the edge portion 112 comprises a portion of the inner face 111a of the first wall 111 adjacent to the end face 112a and a portion of the outer face 111b.

The projection 113 protrudes in the direction along the Y-axis from the inner face 111a of the first wall 111 at the edge portion 112. The projection 113 is a rib extending along the edge portion 112. The projection 113 comprises a first side face 113a and a second side face 113b located on the opposite side of the first side face 113a. The first side face 113a is continuous with the end face 112a of the edge portion 112.

A hole 114 is provided on the projection 113. The hole 114 exists between the tip 113c of the projection 113 and the edge portion 112 (the inner face 111a of the first wall 111). The hole 114 penetrates through the projection 113 in the direction along the Z-axis.

The antenna cover 103 comprises a second wall 121 and a fastening portion 122. The second wall 121 extends from the edge portion 112 of the rear cover 102. The second wall 121 is in a circular arc shape.

The second wall 121 comprises an inner face 121a and an outer face 121b. The inner face 121a faces the inside of the second housing 37 in the direction along the Y-axis. The outer face 121b is located on the opposite side of the inner face 121a and is continuous with the outer face 111b of the first wall 111.

The fastening portion 122 covers the projection 113 and is fastened to the projection 113. That is, the fastening portion 122 is fastened to the first side face 113a of the projection 113 and also is fastened to the second side face 113b. A portion of the fastening portion 122 is filled in the hole 114.

The display portion 12 further comprises a communication antenna 130. The communication antenna 130 may also be referred to as a communication portion or component, for example. The communication antenna 130 is, for example, an antenna that performs wireless communications by using a mobile communications system or a wireless LAN. The communication antenna 130 faces the antenna cover 103 and performs wireless communications through the antenna cover 103.

According to the second embodiment described above, the second portion of the device is not limited to the one that blocks the opening provided on the first portion and may exist on an end of the first portion. The second portion may also exist in a notch or a recess provided on the first portion, for example.

According to at least one of the embodiments described above, the fastening portion of the second portion is fastened to the projection of the first portion. Thus, the shift of the second portion with respect to the first portion is suppressed.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

For example, in the above-described embodiments, an example of a component is the NFC portion 26; however, the component may be another component such as a touchpad or a touch panel, for example. The touchpad detects the movement of a finger of the user through the second wall made of a resin, for example.

What is claimed is:

1. A device comprising:
a first portion comprising a first material,
a first wall extending in a first direction,
an edge portion of the first wall, and
a projection protruding from the edge portion in a second direction intersecting the first direction; and
a second portion comprising a second material,
a second wall extending from the edge portion of the first wall, and
a fastening portion configured to be fastened to the projection.

2. The device of claim 1, wherein
the first portion comprises an opening in the first wall and surrounded by the edge portion, and
the second wall is configured to fill the opening.

3. The device of claim 2, wherein the projection is apart from the opening.

4. The device of claim 3, wherein the projection extends along the edge portion.

5. The device of claim 4, wherein
the projection comprises a hole between a tip of the projection and the edge portion in the second direction, and
a portion of the fastening portion is in the hole.

6. The device of claim 5, wherein the hole comprises a hollow in the projection.

7. The device of claim 6, wherein
the projection comprises a plurality of protruding portions separated from each other, protruding from the edge portion in the second direction, and extending along the edge portion, and
the fastening portion is configured to fasten to the protruding portions.

8. The device of claim 7, wherein the fastening portion comprises a plurality of covering portions configured to cover the protruding portions and a connecting portion extending from one of the covering portions to another one of the covering portions.

9. The device of claim 8, wherein the connecting portion is thinner than a covering portion.

10. The device of claim 9, wherein
the first wall comprises a first face comprising the projection and a second face opposite the first face, and
a surface of the projection is rougher than the second face.

11. The device of claim 10, further comprising:
a housing comprising the first portion and the second portion; and
a component in the housing and facing the second wall.

12. The device of claim 11, wherein the component comprises an antenna.

13. The device of claim 12, further comprising a mark configured to cover a border line between the second face of the first wall and the second wall, the mark extending along the edge portion.

14. The device of claim 12, wherein the second wall comprises:
a third face facing the same direction as the second face; and
a recess provided on the third face, is adjacent to the edge portion, and is extending along the edge portion.

15. The device of claim 1, wherein
the projection comprises a hole between a tip of the projection and the edge portion in the second direction, and a part of the fastening portion is in the hole.

16. The device of claim 15, wherein the projection is apart from an end of the edge portion.

17. The device of claim 16, wherein the projection extends along the edge portion.

18. The device of claim 17, wherein the hole comprises a hollow in the projection.

19. A forming method comprising:
mounting a mold on a first portion comprising a first material,
the first portion comprising
a first wall extending in a first direction,
an edge portion of the first wall, and
a projection protruding from the edge portion in a second direction intersecting the first direction; and
pouring a second material into the mold to form a second portion comprising
a second wall extending from the edge portion of the first wall and
a fastening portion configured to fasten to the projection.

20. The forming method of claim 19, further comprising pouring the second material into the mold to fill, the second material configured to form the fastening portion by filling a hole in the projection between a tip of the projection and the edge portion in the second direction.
